(19) United States
(12) Patent Application Publication
(10) Pub. No.: US 2022/0149085 A1
(43) Pub. Date: May 12, 2022

(54) ARRAY SUBSTRATE, METHOD OF MANUFACTURING SAME, AND DISPLAY PANEL

(71) Applicant: WUHAN CHINA STAR OPTOELECTRONICS TECHNOLOGY CO., LTD., Wuhan (CN)

(72) Inventors: Juncheng Xiao, Wuhan (CN); Fei Ai, Wuhan (CN); Guoheng Yin, Wuhan (CN); Yong Xu, Wuhan (CN)

(21) Appl. No.: 16/954,253

(22) PCT Filed: Dec. 30, 2019
(86) PCT No.: PCT/CN2019/129773

§ 371 Date: Jun. 16, 2020

(30) Foreign Application Priority Data
Oct. 28, 2019 (CN) 201911029531.2

(51) Int. Cl. H01L 27/12

(52) U.S. Cl. CPC H01L 27/1288; G02F 1/134363; H01L 27/1225; H01L 27/1251

(57) ABSTRACT

The present invention provides a TFT array substrate, a manufacturing method thereof, and a display panel thereof, wherein the thin-film transistor (TFT) array substrate is defined with a first area and a second area, and includes a substrate layer, wherein a first TFT is disposed on the substrate layer in the first area, and a second TFT is disposed on the substrate layer in the second area; and wherein the first TFT is a top-gate TFT, the second TFT is a bottom-gate TFT, and a material used for a source/drain layer of the first TFT is same as a material used for a gate layer of the second TFT. The present invention provides a TFT array substrate, which adopts a novel film structure design, so that a low temperature poly-silicon (LTPS) TFT and Oxide TFT provided thereon can have great compatibility in the design and manufacturing process.

### BACKGROUND OF INVENTION

### Field of Invention

The present invention relates to a technical field of flat panel display, in particular to an array substrate, a method of manufacturing the same, and a display panel thereof.

### Description of Prior Art

It is known that with the continuous development of display technology, new flat panel displays have begun to completely replace CRT displays and become mainstream display devices on the market.

A liquid crystal display (LCD) is widely used in various consumer electronics products, such as mobile phones, televisions, personal digital assistants, digital cameras, notebook computers, desktop computers, and the like due to its high picture quality, power saving, thin body, and wide range of applications, and have become the mainstream in display devices.

In recent years, LCD devices have exhibited development trends of high resolution, narrow bezels, and low power consumption. In order to find a more power-efficient way under limitation of the space and battery capacity, low temperature poly-oxide (LTPO) display technology came into being, which uses low temperature poly-silicon (LTPS) thin film transistors in a GOA area of the display panel and oxide thin film transistors in an AA area. The LTPS technology has high mobility, small size and fast charging, which can effectively reduce a size of a frame, and IGZO technology has a small dark current and can be driven at low frequencies, such that narrow bezel and low power consumption functions can be achieved at the same time.

For the LTPO array substrate, there are many incompatibility problems in designs and processes between the LTPS TFT and the Oxide TFT provided thereon. For example, the incompatibility problems may include that a pre-clean solution (HF solution) used in an SD process of the LTPS TFT will etch an IGZO layer in the Oxide TFT; after an ILD layer in the LTPS TFT is completed, it contains a large amount of residual H therein, resulting in damage of electrical properties of the IGZO layer of the Oxide TFT; requirements on film thicknesses of common layers of the LTPS TFT and the Oxide TFT are inconsistent; and etching of deep holes differs from etching of shallow holes due to the different thicknesses of the common layers of the LTPS TFT and the Oxide TFT.

Therefore, there is indeed a need to develop a new type of TFT array substrate to overcome the defects in the prior art.

### SUMMARY OF INVENTION

An aspect of the present invention is to provide a TFT array substrate, which adopts a novel film structure design, so that a low temperature poly-silicon (LTPS) TFT and Oxide TFT provided thereon can have great compatibility in the design and manufacturing process, thereby effectively reducing a process risk of the LTPO array substrate where the LTPS TFT and the Oxide TFT are both located.

Technical solutions adopted by the present invention are as follows:

A thin-film transistor (TFT) array substrate, defined with a first area and a second area, and including a substrate layer, wherein a first TFT is disposed on the substrate layer in the first area, and a second TFT is disposed on the substrate layer in the second area; and wherein the first TFT is a top-gate TFT, the second TFT is a bottom-gate TFT, and a material used for a source/drain layer of the first TFT is same as a material used for a gate layer of the second TFT.

Further, in different embodiments, the source/drain layer of the first TFT and the gate layer of the second TFT are formed in a same process.

Further, in different embodiments, the first area is a gate on array (GOA) area and the first TFT is a low temperature poly-silicon (LTPS) type TFT.

Further, in different embodiments, the second area is a display area, and the second TFT is an oxide semiconductor type TFT.

Further, in different embodiments, a material used for an oxide semiconductor layer as an active layer of the second TFT includes one of oxide semiconductor materials of In-Ga—Zn-O, In—Ga—O, Ga—Zn-O, In—Hf—Zn—O, In—Sn—Zn—O, In—Sn—O, In—Zn—O, Zn—Sn—O, and In—Al—Zn—O.

Further, another aspect of the present invention is to provide a method of manufacturing the TFT array substrate according to the present invention, which includes the following steps:

step S1: providing the substrate layer defined with the first area and the second area, and forming the first TFT on the substrate layer in the first area; and

step S2: forming the second TFT on the substrate layer in the second area,

wherein, in step S1, the gate layer of the second TFT is also formed while forming the source/drain layer of the first TFT, so that the source/drain layer of the first TFT and the gate layer of the second TFT are formed in the same process. That is, the source/drain layer of the first TFT and the gate layer of the second TFT are completed at the same time. In an embodiment, the step S1 can be performed by depositing a conductive layer on the substrate, and then patterning the conductive layer. As a result of etching, the conductive layer becomes the source/drain layer of the first TFT and the gate layer of the second TFT after the patterning.

Further, in different embodiments, in the step S1, the step of forming the first TFT includes the following sub-steps:

S11: forming an active layer of poly-type on the first area;

S12: forming a first gate insulating layer (GI) on the active layer;

S13: forming a first metal layer (M1) as a gate layer (GE1) on the gate insulating layer;

S14: forming an interlayer dielectric layer (ILD) on the first metal layer; and

S15: forming a second metal layer (M2) as the source/drain layer on the interlayer dielectric layer,

wherein, in the step S15, the second metal layer is blanketly deposited on the first area and the second area, and then patterned and etched to form the source/drain layer of the first TFT in the first area and the gate layer (GE2) of the second TFT in the second area respectively.

Further, in different embodiments, in the step S2, the step of forming the second TFT includes the following sub-steps:

S21: forming a second gate insulating layer (GI2) on the first area and the second area, and forming a semiconductor metal oxide layer as an active layer on the second gate insulating layer in the second area;

S22: forming an etch stop layer on the first area and the second area, wherein the etch stop layer (ESL) is disposed on the semiconductor metal oxide layer in the second area; and

S23: forming a third metal layer (M3) as a source/drain layer of the second TFT on the etch stop layer in the second area.

Further, in different embodiments, the method of manufacturing the TFT array substrate according to the present invention further includes step S3: forming a planarization layer, a common electrode layer, a passivation layer, and a pixel electrode layer included in the TFT array substrate.

Further, another aspect of the present invention is to provide a display panel using the TFT array substrate according to the present invention.

Further, in different embodiments, the display panel is preferably an LCD display panel.

Compared with the prior art, the present invention has beneficial effects that a TFT array substrate according to the present invention adopting a new functional layer structure is manufactured by a new process, which prepares two different types of TFTs in different areas on the glass substrate afterwards, so that the preparation of the first TFT does not impact the preparation of the second TFT, thereby reducing the process risk of the entire TFT array substrate, and further improving the device stability.

Further, a new functional layer scheme adopted by the present invention also correspondingly optimizes the manufacturing process of the TFT array substrate where the functional layer is located. By adopting the same material used for the source/drain layer of the first TFT and the gate layer of the second TFT, the manufacturing processes of the first TFT and the second TFT are skillfully joined together in this step, that is, the source/drain layer of the first TFT and the gate layer of the second TFT are completed simultaneously in the same masking process by patterning the same conductive layer, instead of performing the manufacturing processes of the two types of TFTs independently and sequentially. Correspondingly, a mask process is omitted in manufacturing of the entire array substrate, thereby to a certain extent, not only saving the overall manufacturing steps of the TFT array substrate involved in the present invention, but also saving its manufacturing cost.

An aspect of the present invention is to provide a TFT array substrate, which adopts a novel film structure design, so that a low temperature poly-silicon (LTPS) TFT and Oxide TFT provided thereon can have great compatibility in the design and manufacturing process, thereby effectively reducing a process risk of the LTPO array substrate where the LTPS TFT and the Oxide TFT are both located.

### BRIEF DESCRIPTION OF DRAWINGS

In order to more clearly illustrate the embodiments or the technical solutions of the existing art, the drawings illustrating the embodiments or the existing art will be briefly described below. Obviously, the drawings in the following description merely illustrate some embodiments of the present invention. Other drawings may also be obtained by those skilled in the art according to these figures without paying creative work.

FIG. 1 is a schematic structural diagram of a method of manufacturing a TFT array substrate provided in an embodiment of the present invention after the sub-step S11 in the step S1 is completed.

FIG. 2 is a schematic structural diagram of the method of manufacturing the TFT array substrate shown in FIG. 1 after the sub-step S12 in the step S1 is completed.

FIG. 3 is a schematic structural diagram of the method of manufacturing the TFT array substrate shown in FIG. 1 after the sub-steps S13 in the step S1 is completed.

FIG. 4 is a schematic structural diagram of the method of manufacturing the TFT array substrate shown in FIG. 1 after the sub-step S14 in the step S1 is completed.

FIG. 5 is a schematic structural diagram of the method of manufacturing the TFT array substrate shown in FIG. 1 after the sub-step S15 in the step S1 is completed.

FIG. 6 is a schematic structural diagram of the method of manufacturing the TFT array substrate shown in FIG. 1 after the sub-step S21 in the step S2 is completed.

FIG. 7 is a schematic structural diagram of the method of manufacturing the TFT array substrate shown in FIG. 1 after the S22 sub-step in the step S2 is completed.

FIG. 8 is a schematic structural diagram of the method of manufacturing the TFT array substrate shown in FIG. 1 after the S23 sub-step in the step S2 is completed.

FIG. 9 is a schematic structural diagram of the method of manufacturing the TFT array substrate shown in FIG. 1 after the step S3 is completed.

### DETAILED DESCRIPTION OF PREFERRED EMBODIMENTS

The following description of the various embodiments is provided to illustrate the specific embodiments of the invention. The spatially relative directional terms mentioned in the present invention, such as “upper”, “lower”, “before”, “after”, “left”, “right”, “inside”, “outside”, “side”, etc. and the like, may be used herein for ease of description to describe one element or feature's relationship to another element(s) or feature(s) as illustrated in the figures which are merely references. The spatially relative terms are intended to encompass different orientations in addition to the orientation as depicted in the figures.

Embodiments of the present invention will be described in detail herein with reference to the drawings. The present invention may take many different forms, and the present invention should not be construed as merely the specific embodiments set forth herein. The embodiments of the present invention are provided to explain the practical application of the present invention, so that those skilled in the art can understand various embodiments of the present invention and various modifications suitable for a specific intended application.

Hereinafter, technical solutions of a TFT array substrate, a manufacturing method thereof, and a display panel thereof according to the present invention will be further described in detail with reference to the accompanying drawings and embodiments.

Since the present invention also relates to a TFT array substrate and a method of manufacturing the same, in order to avoid unnecessary repetition, the structure of the TFT array substrate according to the present invention will be described exemplarily in combination with the method of manufacturing the TFT array substrate according to the present invention.

An embodiment of the present invention provides a method of manufacturing a TFT array substrate, which includes the following steps:

Step S1, providing the substrate layer defined with the first area 100 and the second area 200, and forming the first TFT on the substrate layer in the first area. The first area 100 is preferably a GOA area, and the second area 200 is preferably a display area (AA area). The substrate layer may specifically include a glass substrate layer (Array Glass) 101 and a buffer layer (Buffer) 102 disposed thereon, but is not limited thereto.

Specific implementation includes the following sub-steps:

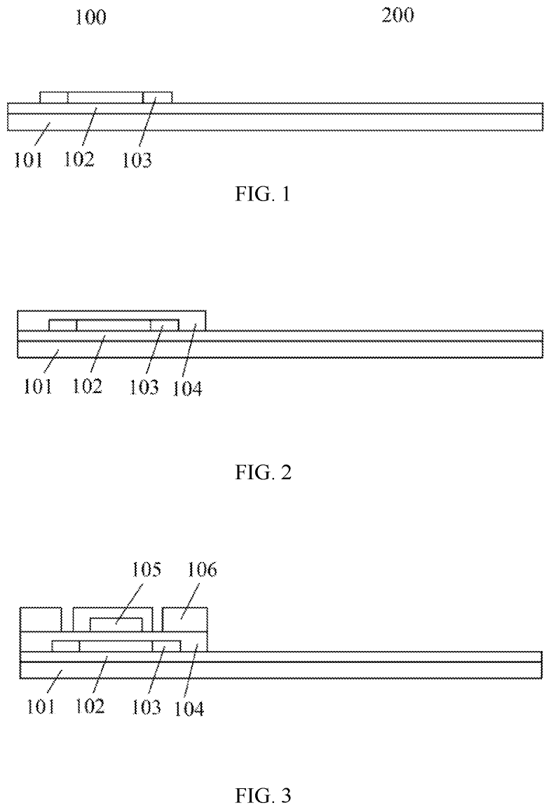

S11. forming an active layer 103 of poly-type on the buffer layer 102 of the first area 100 through the Mask 1 and Mask 2 processes sequentially, and a diagram of the completed structure is shown in FIG. 1.

S12. forming a first gate insulating layer (GI) 104 on the active layer 103, and a diagram of the completed structure is shown in FIG. 2.

S13. forming a first metal layer (M1) 105 as a gate layer (GE1) on the gate insulating layer 104 through a Mask 3 process, and a diagram of the completed structure is shown in FIG. 3.

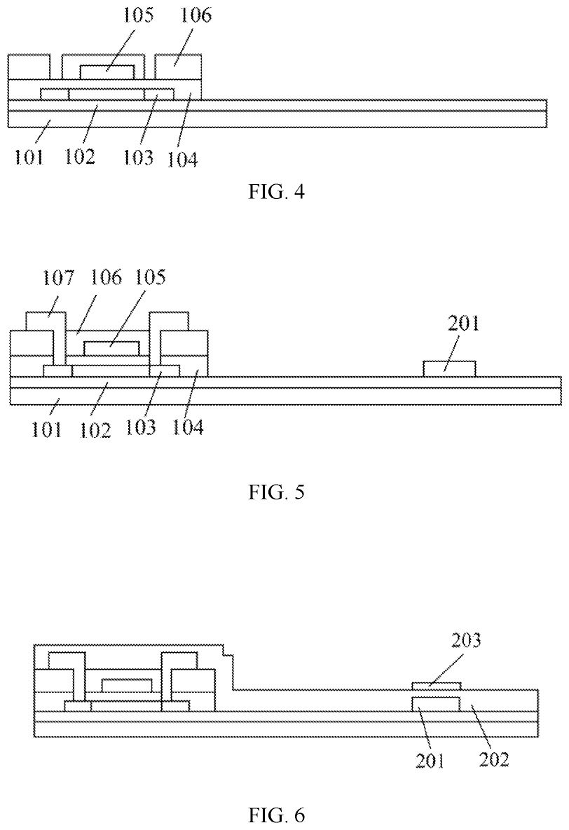

S14. forming an interlayer dielectric layer (ILD) 106 on the first metal layer 105 through a Mask 4 process, and the completed structure is shown in FIG. 4.

S15. forming a second metal layer (M2) on the interlayer dielectric layer as a source/drain layer 107 of the first TFT through a Mask 5 process.

In the step S15, the second metal layer is blanketly deposited on the first area 100 and the second area 200, and then patterned and etched to form the source/drain layer 107 of the first TFT in the first area and the gate layer (GE2) 201 of the second TFT in the second area, respectively.

step S2: forming the second TFT on the substrate layer in the second area 200.

S21. forming a second gate insulating layer (GI2) 202 on the first area 100 and the second area 200 through a Mask 6 process, and forming a semiconductor metal oxide layer (IGZO) 203 as an active layer (Active) on the second gate insulating layer 202 on the second area 200. A diagram of the completed structure is shown in FIG. 6.

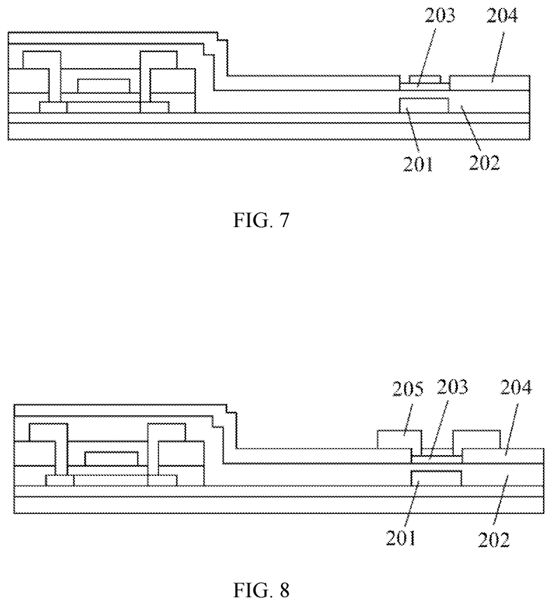

S22. forming an etch stop layer (ESL) 204 on the first area 100 and the second area 200 through a Mask 7 process, wherein the etch stop layer 204 is disposed on the semiconductor metal oxide layer 203 in the second area 200, and a diagram of the completed structure is shown in FIG. 7.

S23. forming a third metal layer (M3) 205 as a source/drain layer of the second TFT on the etch stop layer 204 in the second area by a Mask 8 process, and a diagram of the completed structure is shown in FIG. 8.

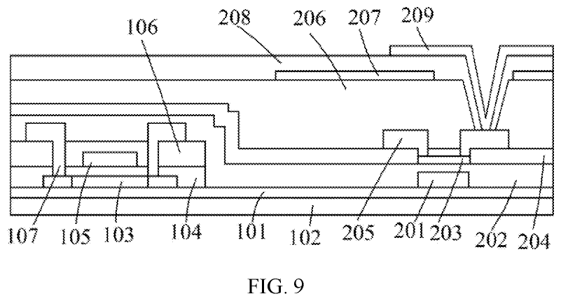

Step S3: forming a planarization layer (PLN) 206, a common electrode layer (BITO) 207, a passivation layer (PV) 208, and a pixel electrode layer (ITO) 209 included in the TFT array substrate by Mask 9 to Mask 12 processes, respectively, and a diagram of the completed structure is shown in FIG. 9. Meanwhile, the array substrate structure shown in FIG. 9 is also a complete illustration of the array substrate according to the present invention.

Further, another aspect of the present invention is to provide a display panel using the TFT array substrate according to the present invention. The display panel is preferably an LCD display panel.

Compared with the prior art, the present invention has beneficial effects that a TFT array substrate according to the present invention adopting a new functional layer structure is manufactured by a new process, which prepares two different types of TFTs in different areas on the glass substrate afterwards, so that the preparation of the first TFT does not impact the preparation of the second TFT, thereby reducing the process risk of the entire TFT array substrate, and further improving the device stability.

Further, a new functional layer scheme adopted by the present invention also correspondingly optimizes the manufacturing process of the TFT array substrate where the functional layer is located. By adopting the same material used for the source/drain layer of the first TFT and the gate layer of the second TFT, the manufacturing processes of the first TFT and the second TFT are skillfully joined together in this step, that is, the source/drain layer of the first TFT and the gate layer of the second TFT are completed simultaneously in the same masking process by patterning the same conductive layer, instead of performing the manufacturing processes of the two types of TFTs independently and sequentially. Correspondingly, Correspondingly, a mask process is omitted in manufacturing of the entire array substrate, thereby to a certain extent, not only saving the overall manufacturing steps of the TFT array substrate involved in the present invention, but also saving its manufacturing cost.

The technical scope of the present invention is not limited to the content in the description. Those skilled in the art can make various variations and modifications to the embodiment without departing from the technical idea of the present invention, and these variations and modifications are It should be within the scope of the present invention.

What is claimed is:

1. A thin-film transistor (TFT) array substrate, defined with a first area and a second area, and comprising a substrate layer, wherein a first TFT is disposed on the substrate layer in the first area, and a second TFT is disposed on the substrate layer in the second area; and
wherein the first TFT is a top-gate TFT, the second TFT is a bottom-gate TFT, and a material used for a source/drain layer of the first TFT is same as a material used for a gate layer of the second TFT.

2. The TFT array substrate according to claim 1, wherein the source/drain layer of the first TFT and the gate layer of the second TFT are formed in a same process.

3. The TFT array substrate according to claim 1, wherein the first area is a gate on array (GOA) area and the first TFT is a low temperature poly-silicon (LTPS) type TFT.

4. The TFT array substrate according to claim 1, wherein the second area is a display area, and the second TFT is an oxide semiconductor type TFT.

5. The TFT array substrate according to claim 4, wherein a material used for an oxide semiconductor layer as an active layer of the second TFT comprises one of oxide semiconductor materials of In-Ga—Zn-O, In—Ga—O, Ga—Zn-O, In—Hf—Zn—O, In—Sn—Zn—O, In—Sn—O, In—Zn—O, Zn—Sn—O, and In—Al—Zn—O.

6. A method of manufacturing the TFT array substrate according to claim 1, comprising the following steps:
step S1: providing the substrate layer defined with the first area and the second area, and forming the first TFT on the substrate layer in the first area; and
step S2: forming the second TFT on the substrate layer in the second area,
wherein, in step S1, the gate layer of the second TFT is also formed while forming the source/drain layer of the first TFT, so that the source/drain layer of the first TFT and the gate layer of the second TFT are formed in the same process.

7. The manufacturing method according to claim 6, wherein in the step S1, the step of forming the first TFT comprises the following sub-steps:
S11: forming an active layer of poly-type on the first area;
S12: forming a first gate insulating layer on the active layer;
S13: forming a first metal layer as a gate layer on the gate insulating layer;
S14: forming an interlayer dielectric layer on the first metal layer; and
S15: forming a second metal layer as the source/drain layer on the interlayer dielectric layer,
wherein, in the step S15, the second metal layer is blanketly deposited on the first area and the second area, and then patterned and etched to form the source/drain layer of the first TFT in the first area and the gate layer of the second TFT in the second area respectively.

8. The manufacturing method according to claim 6, wherein in the step S2, the step of forming the second TFT comprises the following sub-steps:
S21: forming a second gate insulating layer on the first area and the second area, and forming a semiconductor metal oxide layer as an active layer on the second gate insulating layer in the second area;
S22: forming an etch stop layer on the first area and the second area, wherein the etch stop layer is disposed on the semiconductor metal oxide layer in the second area; and
S23: forming a third metal layer as a source/drain layer of the second TFT on the etch stop layer in the second area.

9. The manufacturing method according to claim 6, further comprising step S3: forming a planarization layer, a common electrode layer, a passivation layer, and a pixel electrode layer comprised in the TFT array substrate.

10. A display device, comprising the TFT array substrate according to claim 1.
